(19) United States
(12) Patent Application Publication
(10) Pub. No.: US 2018/0226361 A1
(43) Pub. Date: Aug. 9, 2018

(54) CONTROLLED STANDOFF FOR MODULE WITH BALL GRID ARRAY

(71) Applicant: SKYWORKS SOLUTIONS, INC., Woburn, MA (US)

(72) Inventors: Howard E. CHEN, Anaheim, CA (US); Hoang Mong NGUYEN, Fountain Valley, CA (US)

(21) Appl. No.: 15/883,322

(22) Filed: Jan. 30, 2018

Related U.S. Application Data
(60) Provisional application No. 62/451,775, filed on Jan. 30, 2017.

(51) Int. Cl. H01L 23/00; H01L 25/065; H01L 25/00

(52) U.S. Cl. CPC H01L 23/562; H01L 2225/0652; H01L 25/50; H01L 25/0652

(57) ABSTRACT

Controlled standoff for module with ball grid array. In some embodiments, a packaged module can include a packaging substrate having an underside, and an arrangement of conductive features implemented on the underside of the packaging substrate to define an underside area and to allow mounting of the packaged module on a circuit board. The packaged module can further include an underside component mounted to the underside of the packaging substrate within the underside area. The packaged module can further include one or more standoff structures implemented on the underside of the packaging substrate and configured to inhibit damage to the underside component when some or all of the arrangement of conductive features collapses during or after mounting of the packaged module on the circuit board.

### CROSS-REFERENCE TO RELATED APPLICATION(S)

This application claims priority to U.S. Provisional Application No. 62/451,775 filed Jan. 30, 2017, entitled CONTROLLED STANDOFF FOR MODULE WITH BALL GRID ARRAY, the disclosure of which is hereby expressly incorporated by reference herein in its respective entirety.

### BACKGROUND

### Field

The present disclosure relates to packaged radio-frequency (RF) modules.

### Description of the Related Art

In many radio-frequency (RF) applications, one or more integrated circuits are implemented in a packaged module. Such a packaged module typically includes a packaging substrate and one or more semiconductor die mounted on the packaging substrate. The packaged module can also include one or more surface-mount technology (SMT) devices having, for example, respective passive circuit elements. Such SMT device(s) can also be mounted on the packaging substrate.

### SUMMARY

In accordance with some implementations, the present disclosure relates to a packaged module that includes a packaging substrate having an underside, and an arrangement of conductive features implemented on the underside of the packaging substrate to define an underside area and to allow mounting of the packaged module on a circuit board. The packaged module further includes an underside component mounted to the underside of the packaging substrate within the underside area. The packaged module further includes one or more standoff structures implemented on the underside of the packaging substrate and configured to inhibit damage to the underside component when some or all of the arrangement of conductive features collapses during or after mounting of the packaged module on the circuit board.

In some embodiments, the arrangement of conductive features can include an array of conductive pillars. In some embodiments, the arrangement of conductive features can include a ball grid array.

In some embodiments, the underside component can include a semiconductor die or a surface-mount technology (SMT) device. The packaged module can further include an upper-side component mounted to an upper side of the packaging substrate, such that the packaged module is a dual-sided module having the ball grid array. The underside component and the upper-side component can be parts of, for example, a radio-frequency circuit. The packaged module can further include an overmold implemented on the upper side of the packaging substrate. The packaged module can further include a conformal shield layer implemented to cover an upper surface of the overmold and side walls defined by the overmold and the packaging substrate.

In some embodiments, at least some of the one or more standoff structures can be an electrical insulator. In some embodiments, at least some of the one or more standoff structures can be an electrical conductor. In some embodiments, at least some of the one or more standoff structures can be configured to provide an electrical connection between the packaging substrate and the circuit board. In some embodiments, at least some of the one or more standoff structures can be configured to be without an electrical connection with the circuit board.

In some embodiments, at least some of the one or more standoff structures can have a melting point that is higher than a melting point of the conductive features. In some embodiments, at least some of the one or more standoff structures can have a ball shape or a post shape.

In some embodiments, the one or more standoff structures can include a plurality of standoff structures arranged about the underside component. The plurality of standoff structures can include a standoff structure positioned near each corner of the underside component.

In some teachings, the present disclosure relates to a method for manufacturing a packaged module. The method includes forming or providing a packaging substrate having an underside, and arranging conductive features on the underside of the packaging substrate to allow the packaged module to be capable of being mounted on a circuit board, and to provide an underside area. The method further includes mounting an underside component to the underside of the packaging substrate within the underside area. The method further includes implementing one or more standoff structures on the underside of the packaging substrate to inhibit damage to the underside component when some or all of the arrangement of conductive features collapses during or after mounting of the packaged module on the circuit board.

In a number of implementations, the present disclosure relates to a wireless device that includes a circuit board configured to receive a plurality of modules, a transceiver implemented on the circuit board, and an antenna in communication with the transceiver and configured to facilitate either or both of transmission and reception of respective signals. The wireless device further includes a radio-frequency module mounted on the circuit board with an arrangement of conductive features between an underside of the radio-frequency module and the circuit board such that at least a portion of the radio-frequency module is electrically between the transceiver and the antenna. The radio-frequency module further includes an underside component mounted to the underside of the radio-frequency module. The wireless device further includes one or more standoff structures implemented between the underside of the radio-frequency module and the circuit board, and configured to inhibit damage to the underside component when some or all of the arrangement of conductive features collapses.

In some embodiments, the conductive features can be parts of the radio-frequency module. The conductive features can be arranged as, for example, a ball grid array.

In some embodiments, at least some of the one or more standoff structures can be part of the radio-frequency module. In some embodiments, at least some of the one or more standoff structures can be part of the circuit board.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a side sectional view of an example dual-sided module having a ball grid array (BGA) on its underside.

FIG. 2 shows an example where the dual-sided BGA module of FIG. 1 is mounted on a circuit board.

FIG. 3 depicts a side sectional view of an example dual-sided module having a ball grid array (BGA) and one or more standoff structures on its underside, and mounted on a circuit board.

FIG. 4 shows that in some embodiments, the standoff structure of FIG. 3 can be a solder ball or a similarly-shaped structure dimensioned to be soldered to a contact pad associated with a packaging substrate of the module, and also configured to be soldered to a contact pad associated with the circuit board.

FIG. 5 shows that in some embodiments, the standoff structure of FIG. 3 can be a solder ball or a similarly-shaped structure dimensioned to be soldered to a contact pad associated with a packaging substrate of the module, but not to the circuit board.

FIG. 6A shows the standoff structure of FIG. 5 and a mounted situation where the standoff solder ball remains unattached to the circuit board and has an offset gap when the module-to-circuit board orientation is in a normal state.

FIG. 6B shows the mounted configuration of FIG. 6A where a collapsing condition exists such that the bottom end of the standoff solder ball engages the circuit board to thereby inhibit further collapse of the underside of the module onto to the circuit board.

FIG. 7 depicts a side sectional view of another example dual-sided module having a ball grid array (BGA) and one or more standoff structures on its underside, and mounted on a circuit board.

FIG. 8 shows that in some embodiments, the standoff structure of FIG. 7 can be a post or a similarly-shaped structure dimensioned to be soldered to a contact pad associated with a packaging substrate of the module, and also configured to be soldered to a contact pad associated with the circuit board.

FIG. 9 shows that in some embodiments, the standoff structure of FIG. 7 can be a post or a similarly-shaped structure dimensioned to be soldered to a contact pad associated with a packaging substrate of the module, but not to the circuit board.

FIG. 10A shows the standoff structure of FIG. 9 and a mounted situation where the standoff post remains unattached to the circuit board and has an offset gap when the module-to-circuit board orientation is in a normal state.

FIG. 10B shows the mounted configuration of FIG. 10A where a collapsing condition exists such that the bottom end of the standoff post engages the circuit board to thereby inhibit further collapse of the underside of the module onto to the circuit board.

FIG. 11 shows an example of the underside of the module of FIG. 3, where a plurality standoff solder balls can be placed at selected locations to inhibit or reduce the likelihood of collapse of the module onto a circuit board.

FIG. 12 shows an example of the underside of the module of FIG. 7, where a plurality standoff posts can be placed at selected locations to inhibit or reduce the likelihood of collapse of the module onto a circuit board.

FIG. 13 shows an example of a radio-frequency (RF) module having one or more features as described herein.

FIG. 14 shows an example of a wireless device having one or more features as described herein.

### DETAILED DESCRIPTION OF SOME EMBODIMENTS

The headings provided herein, if any, are for convenience only and do not necessarily affect the scope or meaning of the claimed invention.

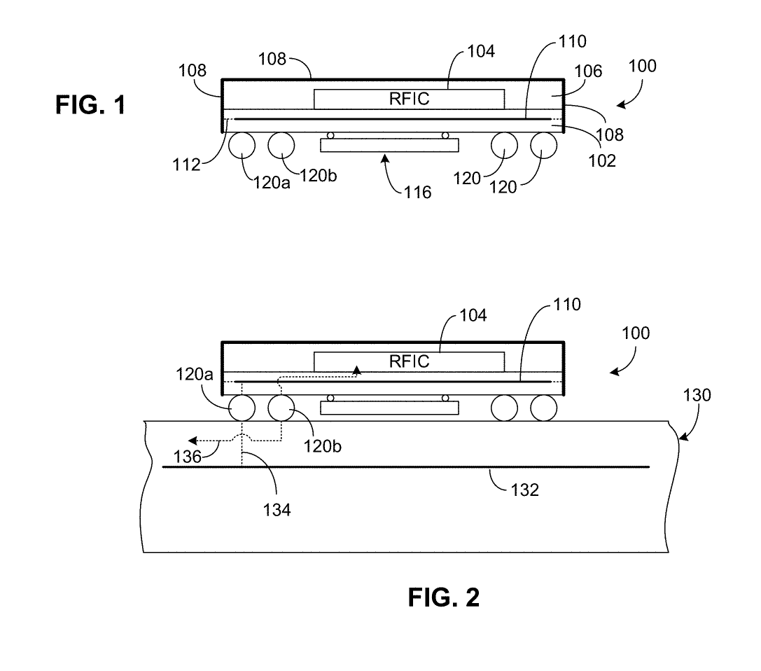

FIG. 1 depicts a side sectional view of an example of a dual-sided module 100 having a ball grid array (BGA) on its underside. More particularly, the module 100 includes a packaging substrate 102 with a radio-frequency (RF) circuit (collectively indicated as 104) implemented on its first side (e.g., upper side), and one or more components (collectively indicated as 116) mounted on its second side (e.g., underside). The RF circuit 104 on the upper side of the packaging substrate 102 can include, for example, one or more semiconductor die, and/or one or more surface-mount technology (SMT) devices. The underside component(s) 116 can include, for example, one or more semiconductor die, and/or one or more SMT devices.

In the example module 100 of FIG. 1, an overmold 106 is shown to be implemented on the upper side of the packaging substrate 102 so as to encapsulate the RF circuit 104. Further, the upper surface of the overmold 106 and the side walls of the module 100 are shown to have a conductive layer 108 (e.g., a conformal conductive layer) that is electrically connected to a ground plane 110 within the packaging substrate 102. Accordingly, the conductive layer 108 and the ground plane 110 generally define an internal volume, and provide RF shielding functionality between the internal volume and external location(s). In some embodiments, the module 100 may or may not include additional shielding functionality (e.g., intra-module shielding between regions within the internal volume).

Although various examples are described herein in the context of modules having such shielding functionalities (e.g., conformal shielding and/or intra-module shielding), one or more features of the present disclosure can also be implemented in modules without such shielding functionalities.

In the example of FIG. 1, the BGA is shown to include a plurality of solder balls 120a, 120b, 120. Such solder balls are shown to be arranged so as to provide an underside volume dimensioned to allow mounting of the underside component(s) 116. Such underside component(s) can be mounted to the underside of the packaging substrate 102 with or without an underfill.

Although various examples are described herein in the context of modules having such a BGA with solder balls, one or more features of the present disclosure can also be implemented in modules with other conductive structures. For example, pillars (e.g., columns, posts, etc.) can be utilized to provide functionalities similar to those of the solder balls.

Among others, additional details related to the foregoing dual-sided module having a BGA can be found in U.S. Patent Application Publication No. 2016/0099192 entitled DUAL-SIDED RADIO-FREQUENCY PACKAGE HAVING BALL GRID ARRAY which is hereby expressly incorporated by reference herein in its entirety.

FIG. 2 shows an example where the dual-sided BGA module 100 of FIG. 1 is mounted on a circuit board 130 (e.g., a phone board). Such a circuit board can be configured to include various electrical connections to facilitate various functionalities of the module 100. For example, a ground of the module 100 (e.g., at the ground plane 110) can be electrically connected to a ground of the circuit board 130 (e.g., at a ground plane 132) through an example solder ball 120a. Such an electrical connection is indicated as 134. In another example, a non-ground electrical connection can be made between the RF circuit 104 of the module 100 and another location (e.g., another module) associated with the circuit board 130, through an example solder ball 120b. Such an electrical connection is indicated as 136. In some embodiments, the non-ground electrical connection 136 can facilitate, for example, power supply, control signal, and RF signal associated with operation of the module 100.

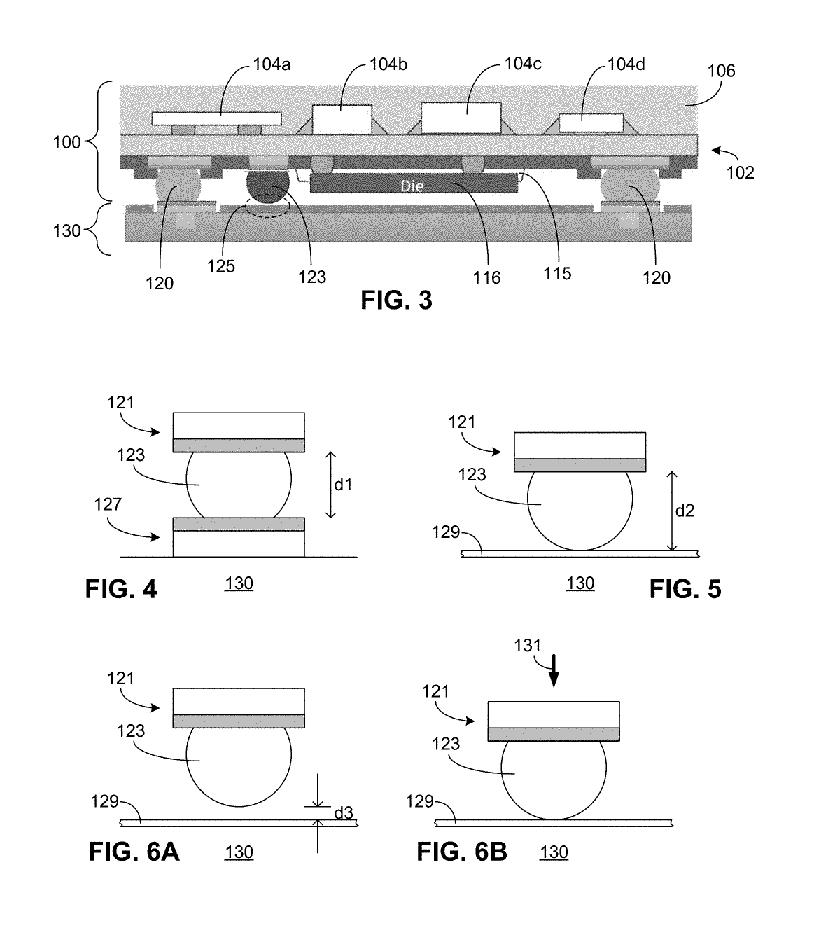

FIG. 3 shows a side sectional view of another example of a dual-sided module 100 having a ball grid array (BGA) on its underside. More particularly, the module 100 includes a packaging substrate 102 with a radio-frequency (RF) circuit implemented with various devices (104a, 104b, 104c, 104d) such as one or more semiconductor die, and/or one or more surface-mount technology (SMT) devices. Such devices are shown to be implemented on a first side (e.g., upper side) of the packaging substrate 102. A second side (e.g., underside) of the packaging substrate 102 is shown to include one or more components (collectively indicated as 116) such as a semiconductor die.

In the example module 100 of FIG. 3, an overmold 106 is shown to be implemented on the upper side of the packaging substrate 102 so as to encapsulate the various components (104a, 104b, 104c, 104d). In the example module 100 of FIG. 3, the upper surface of the overmold 106 and the side walls of the module 100 may or may not have a conductive layer (e.g., a conformal conductive layer) that is electrically connected to a ground plane within the packaging substrate 102. Such a conductive layer and the ground plane generally define an internal volume, and provide RF shielding functionality between the internal volume and external location(s). In some embodiments, the module 100 may or may not include additional shielding functionality (e.g., intra-module shielding between regions within the internal volume).

Although various examples are described herein in the context of modules having such shielding functionalities (e.g., conformal shielding and/or intra-module shielding), one or more features of the present disclosure can also be implemented in modules without such shielding functionalities.

In the example of FIG. 3, the BGA is shown to include a plurality of solder balls 120. Such solder balls are shown to be arranged so as to provide an underside volume dimensioned to allow mounting of the underside component(s) 116. Such underside component(s) can be mounted to the underside of the packaging substrate 102 with an underfill 115.

In some embodiments, each of the module 100 of FIG. 1 and the module 100 of FIG. 3 can include one or more standoff structures. In the example of FIG. 3, such a standoff structure is indicated as 123. In the example of FIG. 1, one or more similar standoff structures can also be provided.

In the example of FIG. 3, the standoff structure 123 is depicted as being between the underside of the module 100 and a circuit board 130 (e.g., a phone board) on which the module is mounted. In some embodiments, one or more of such standoff structures (123) can be implemented on the underside of the packaging substrate 102. In such embodiments, the standoff structures (123) can be part(s) of an unmounted module.

While various examples are described herein in the context of the foregoing configuration where the standoff structure(s) is/are part(s) of a module, it will be understood that one or more features of the present disclosure can also be implemented in other ways. For example, in some embodiments, one or more of such standoff structures (123) can be implemented on a circuit board. In such embodiments, the standoff structures (123) can be part(s) of the circuit board before having a module mounted thereto. In another example, in some embodiments, one or more of such standoff structures (123) can be implemented on the underside of the packaging substrate 102, and one or more of such standoff structures (123) can be implemented on a circuit board. In such embodiments, the standoff structure(s) of the module and the standoff structure(s) of the circuit board can be configured to collectively provide a desired standoff functionality when the module is mounted on the circuit board.

Referring to the example of FIG. 3, the standoff structure(s) 123 can be placed at selected location(s) to prevent or reduce the likelihood of collapse of the underside of the packaging substrate 102. For example, such a collapse can occur where some or all of the solder balls melt in an undesirable manner such that the melted solder balls are unable to support the module 100 when the module is mounted on the circuit board 130 (e.g., a phone board). In some situations, such a collapse can also occur, for example, when a downward force is applied on the upper side of the module 100 during various processing steps. When such a collapse occurs, the underside component 116 such as a die can physically contact the upper surface of the circuit board 130 and become damaged and/or have its contacts with the packaging substrate 102 fail.

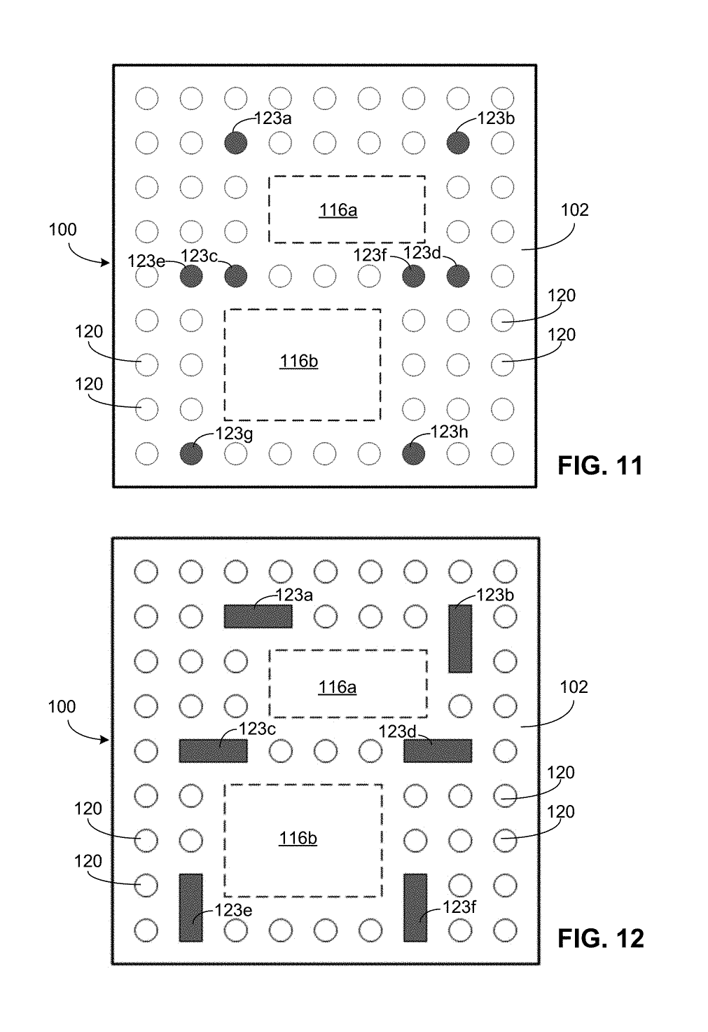

In the example of FIG. 3, a portion indicated as 125 depicts a configuration between the standoff structure 123 and the circuit board 130. Various examples of such a configuration are described herein in reference to FIGS. 4-6. Examples of how one or more of such standoff structures 123 can be arranged laterally with respect to one or more underside components 116 are described herein in reference to FIG. 11.

FIG. 4 shows that in some embodiments, the example standoff structure 123 of FIG. 3 can be a solder ball or a similarly-shaped structure dimensioned to be soldered to, or attached to, a contact pad 121 associated with the packaging substrate (102 in FIG. 3), and also to be soldered to, or attached to, a contact pad 127 associated with the circuit board 130. Accordingly, the standoff solder ball 123 and the contact pads 121, 127 can be dimensioned appropriately in view of the BGA solder balls 120 so as to provide a substantially fixed standoff distance d1 as shown.

In the foregoing example, the standoff solder ball 123 being soldered on both ends can allow formation of an electrical connection through the standoff solder ball 123, between the module 100 and the circuit board 130. Accordingly, in such a configuration, the standoff solder ball 123 can also provide an isolation functionality as described in U.S. patent application Ser. No.______ [Attorney Docket 75900-50368US], entitled SIGNAL ISOLATION FOR MODULE WITH BALL GRID ARRAY, the disclosure of which is filed on even date herewith and hereby incorporated by reference herein in its entirety.

FIG. 5 shows that in some embodiments, the example standoff structure 123 of FIG. 3 can be a solder ball or a similarly-shaped structure dimensioned to be soldered to, or attached to, a contact pad 121 associated with the packaging substrate (102 in FIG. 3). The other end of the standoff solder ball 123 can remain unattached, but physically engage or be very close to an upper surface layer 129 of the circuit board 130. Accordingly, the standoff solder ball 123 and the contact pad 121 can be dimensioned appropriately in view of the BGA solder balls 120 so as to provide a substantially fixed standoff distance d2 as shown.

In some embodiments, the standoff arrangement of FIG. 5 can be configured such that the standoff solder ball 123 does not provide an electrical path between the module 100 and the circuit board 130. For example, the upper surface layer 129 of the circuit board 130 may be an electrically insulating layer. Thus, even if the standoff solder ball 123 is in physical contact with the upper surface layer 129, the insulating property of the upper surface layer 129 prevents electrical conduction through the standoff solder ball 123 between the module 100 and the lower portion of the circuit board 130.

FIG. 6A shows that in some embodiments, the example standoff structure 123 of FIG. 3 can be a solder ball or a similarly-shaped structure dimensioned to be soldered to, or attached to, a contact pad 121 associated with the packaging substrate (102 in FIG. 3). The other end of the standoff solder ball 123 can remain unattached, and have an offset distance d3 (e.g., between the end of the standoff solder ball 123 and an upper surface layer 129) when the module-to-circuit board orientation is in a first state (e.g., a normal state with no collapse of the solder balls). However, and as shown in FIG. 6B, when a collapsing condition exists (e.g., either by collapsing solder balls and/or application of some other downward force 131), the bottom end of the standoff solder ball 123 can physically engage the upper surface layer 129 of the circuit board 130 to thereby inhibit or reduce further collapse of the underside of the module 100 relative to the circuit board 130. Accordingly, the standoff solder ball 123 and the contact pad 121 can be dimensioned appropriately in view of the BGA solder balls 120 so as to provide a standoff distance with a margin d3 as shown.

In some embodiments, the standoff arrangement of FIGS. 6A and 6B can be configured such that the standoff solder ball 123 does not provide an electrical path between the module 100 and the circuit board 130. For example, the gap d3 in the example of FIG. 6A is typically non-conducting, and the upper surface layer 129 of the circuit board 130 may be an electrically insulating layer. Thus, even if the standoff solder ball 123 is in physical contact with the upper surface layer 129 as in the example of FIG. 6B, the insulating property of the upper surface layer 129 prevents electrical conduction through the standoff solder ball 123 between the module 100 and the lower portion of the circuit board 130.

In the examples of FIGS. 3-6, the standoff structure 123 can be an appropriately dimensioned solder ball or a ball shaped structure. It will be understood that a standoff structure having one or more features can have other shapes.

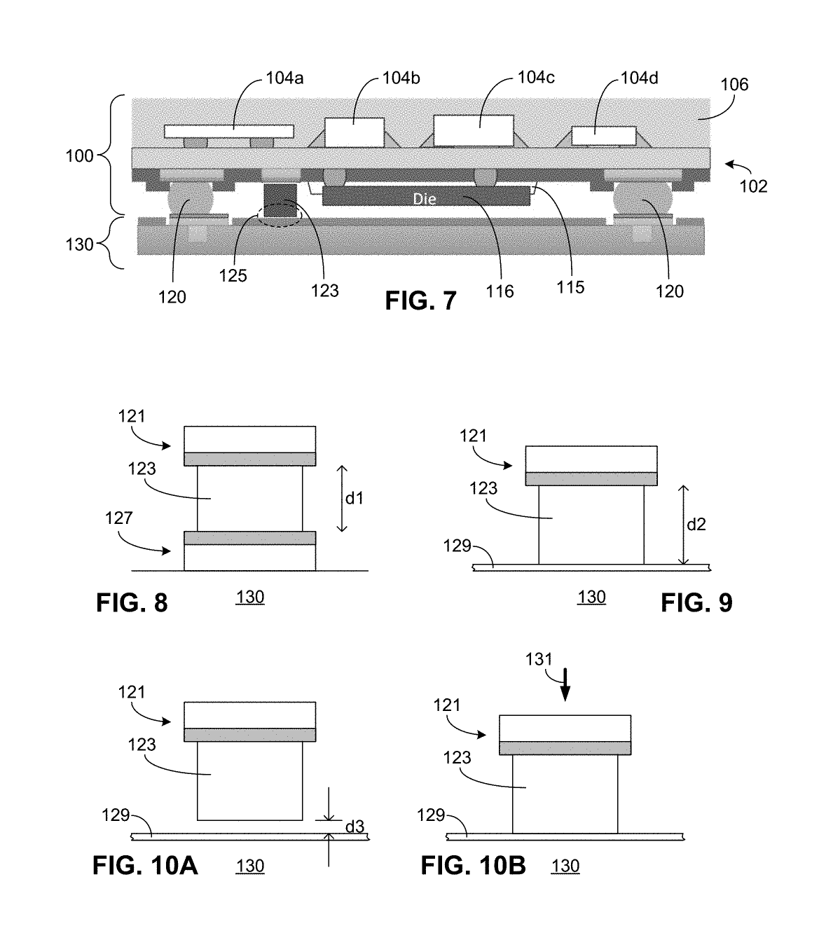

For example, FIG. 7 shows that in some embodiments, a standoff structure having one or more features as described herein can have shapes such as a post, a box-shaped structure, etc. In the example of FIG. 7, other parts of the module 100 can be similar to the example of FIG. 3.

In the example of FIG. 7, a portion indicated as 125 depicts a configuration between the standoff structure 123 and the circuit board 130. Various examples of such a configuration are described herein in reference to FIGS. 8-10. Examples of how one or more of such standoff structures 123 can be arranged laterally with respect to one or more underside components 116 are described herein in reference to FIG. 12.

FIG. 8 shows that in some embodiments, the example standoff structure 123 of FIG. 7 can be a post or a similarly-shaped structure dimensioned to be soldered to, or attached to, a contact pad 121 associated with the packaging substrate (102 in FIG. 7), and also to be soldered to, or attached to, a contact pad 127 associated with the circuit board 130. Accordingly, the standoff post 123 and the contact pads 121, 127 can be dimensioned appropriately in view of the BGA solder balls 120 so as to provide a substantially fixed standoff distance d1 as shown.

In the foregoing example, the standoff post 123 being soldered on both ends can allow formation of an electrical connection through the standoff post 123, between the module 100 and the circuit board 130. Accordingly, in such a configuration, the standoff post 123 can also provide an isolation functionality as described in the above-referenced U.S. patent application Ser. No. ______[Attorney Docket 75900-50368US], entitled SIGNAL ISOLATION FOR MODULE WITH BALL GRID ARRAY.

FIG. 9 shows that in some embodiments, the example standoff structure 123 of FIG. 7 can be a post or a similarly-shaped structure dimensioned to be soldered to, or attached to, a contact pad 121 associated with the packaging substrate (102 in FIG. 7). The other end of the standoff post 123 can remain unattached, but physically engage or be very close to an upper surface layer 129 of the circuit board 130. Accordingly, the standoff post 123 and the contact pad 121 can be dimensioned appropriately in view of the BGA solder balls 120 so as to provide a substantially fixed standoff distance d2 as shown.

In some embodiments, the standoff arrangement of FIG. 9 can be configured such that the standoff post 123 does not provide an electrical path between the module 100 and the circuit board 130. For example, the upper surface layer 129 of the circuit board 130 may be an electrically insulating layer. Thus, even if the standoff post 123 is in physical contact with the upper surface layer 129, the insulating property of the upper surface layer 129 prevents electrical conduction through the standoff post 123 between the module 100 and the lower portion of the circuit board 130.

FIG. 10A shows that in some embodiments, the example standoff structure 123 of FIG. 7 can be a post or a similarly-shaped structure dimensioned to be soldered to, or attached to, a contact pad 121 associated with the packaging substrate (102 in FIG. 7). The other end of the standoff post 123 can remain unattached, and have an offset distance d3 (e.g., between the end of the standoff post 123 and an upper surface layer 129) when the module-to-circuit board orientation is in a first state (e.g., a normal state with no collapse of the solder balls). However, and as shown in FIG. 10B, when a collapsing condition exists (e.g., either by collapsing solder balls and/or application of some other downward force 131), the bottom end of the standoff post 123 can physically engage the upper surface layer 129 of the circuit board 130 to thereby inhibit or reduce further collapse of the underside of the module 100 relative to the circuit board 130. Accordingly, the standoff post 123 and the contact pad 121 can be dimensioned appropriately in view of the BGA solder balls 120 so as to provide a standoff distance with a margin d3 as shown.

In some embodiments, the standoff arrangement of FIGS. 10A and 10B can be configured such that the standoff post 123 does not provide an electrical path between the module 100 and the circuit board 130. For example, the gap d3 in the example of FIG. 10A is typically non-conducting, and the upper surface layer 129 of the circuit board 130 may be an electrically insulating layer. Thus, even if the standoff post 123 is in physical contact with the upper surface layer 129 as in the example of FIG. 10B, the insulating property of the upper surface layer 129 prevents electrical conduction through the standoff post 123 between the module 100 and the lower portion of the circuit board 130.

FIG. 11 shows an underside of a module 100 having a BGA with an array of solder balls 120, and two example components 116a, 116b. In the example of FIG. 11, a plurality standoff structures such as the standoff solder balls of FIGS. 3-6 can be placed at selected locations to inhibit or reduce the likelihood of collapse of the underside of the module 100 onto a circuit board. For example, standoff solder balls 123a, 123b, 123c, 123d can be placed near the four corners of the first component 116a so as to provide standoff support for the first component 116a. Similarly, standoff solder balls 123e, 123f, 123g, 123h can be placed near the four corners of the second component 116b so as to provide standoff support for the second component 116b.

It will be understood that more or less numbers of standoff structures (than the examples of FIG. 11) can be utilized. Further, placement of standoff structures relative to a given component can be different than the corner-placement example of FIG. 11.

FIG. 12 shows an underside of a module 100 having a BGA with an array of solder balls 120, and two example components 116a, 116b. In the example of FIG. 12, a plurality standoff structures such as the standoff posts of FIGS. 7-10 can be placed at selected locations to inhibit or reduce the likelihood of collapse of the underside of the module 100 onto a circuit board. For example, standoff posts 123a, 123b, 123c, 123d can be placed near the four corners of the first component 116a so as to provide standoff support for the first component 116a. Similarly, standoff posts 123e, 123f, along with the foregoing standoff posts 123c, 123d can provide standoff support for the second component 116b.

It will be understood that more or less numbers of standoff structures (than the examples of FIG. 12) can be utilized. Further, placement of standoff structures relative to a given component can be different than the corner-placement example of FIG. 12.

In the examples of FIGS. 3-6 and 11, the standoff structures are described as being standoff solder balls. In the examples of FIGS. 7-10 and 12, the standoff structures are described as being standoff posts. It will be understood that in some embodiments, an underside of a module can include a combination of standoff structures having different shapes. For example, an underside of a module can include one or more standoff solder balls and one or more standoff posts.

In some embodiments, a standoff structure as described herein can be configured to replace one or more existing solder balls or posts that are not needed (e.g., redundant ground pins). In some embodiments, such a standoff structure can be configured as, for example, a metal sphere or post, a solder ball with a solder coated metal core, a metal or ceramic post, a surface-mount technology (SMT) component, a solder mask, or any feature that does not collapse during a reflow process for the BGA solder balls. In some embodiments, a standoff structure having one or more features as described herein can have a melting point that is higher than the melting point of the BGA solder balls. In some embodiments, a standoff structure having one or more features as described herein can be electrically conductive or non-conductive.

In some embodiments, a packaged module having one or more features can be fabricated utilizing, for example, some or all of the manufacturing techniques described in the above-referenced U.S. Patent Application Publication No. 2016/0099192 entitled DUAL-SIDED RADIO-FREQUENCY PACKAGE HAVING BALL GRID ARRAY.

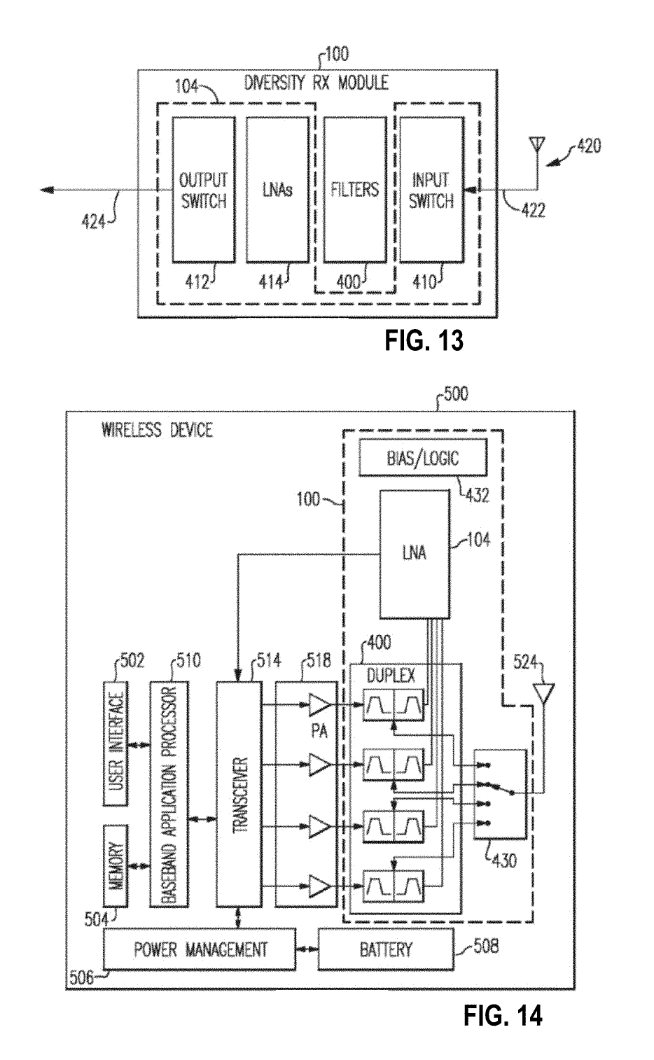

In some implementations, a packaged module having one or more features as described herein can be utilized in various products. For example, FIGS. 13 and 14 show examples of how a packaged module having one or more features as described herein can be configured for use in a wireless device, and/or be implemented in a wireless device. FIG. 13 shows that in some embodiments, a packaged module having one or more features as described herein can be implemented as a diversity receive (RX) module 100. In some applications, such a module can be implemented relatively close to a diversity antenna 420 so as to minimize or reduce losses and/or noise in a signal path 422.

The diversity RX module 100 in the example of FIG. 13 can be configured such that switches 410 and 412, as well as LNAs 414, are implemented in a semiconductor die (depicted as 104) that is mounted underneath a packaging substrate. One or more filters 400 can be mounted on such a packaging substrate as described herein.

As further shown in FIG. 13, RX signals processed by the diversity RX module 100 can be routed to a transceiver through a signal path 424. In wireless applications where the signal path 424 is relatively long and lossy, the foregoing implementation of the diversity RX module 100 close to the antenna 420 can provide a number of desirable features.

It will be understood that one or more features of the present disclosure can also be implemented in packaged modules having functionalities different than that of the diversity receive example of FIG. 13. For example, for any packaged BGA-based module where standoff support is desired on the underside, one or more features as described herein can be implemented.

FIG. 14 shows that in some embodiment a packaged module having one or more features as described herein can be implemented in a wireless device 500. For example, an LNA or LNA-related module 100 can be implemented as a packaged module as described herein, and such a module can be utilized with a main antenna 524.

The example LNA module 100 of FIG. 14 can include, for example, one or more LNAs 104, a bias/logic circuit 432, and a band-selection switch 430. Some or all of such circuits can be implemented in a semiconductor die that is mounted under a packaging substrate of the LNA module 100. In such an LNA module, some or all of duplexers 400 can be mounted on the packaging substrate so as to form a packaged module having one or more features as described herein.

FIG. 14 further depicts various features associated with the example wireless device 500. Although not specifically shown in FIG. 14, a diversity RX module 100 of FIG. 13 can be included in the wireless device 500 with the LNA module 100, in place of the LNA module 100, or any combination thereof. It will also be understood that a packaged module having one or more features as described herein can be implemented in the wireless device 500 as a non-LNA module.

In the example wireless device 500, a power amplifier (PA) circuit 518 having a plurality of PAs can provide an amplified RF signal to a switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

The transceiver 514 is shown to interact with a baseband sub-system 510 that is configured to provide conversion between data and/or voice signals suitable for a user and RF signals suitable for the transceiver 514. The transceiver 514 is also shown to be connected to a power management component 506 that is configured to manage power for the operation of the wireless device 500. Such a power management component can also control operations of the baseband sub-system 510.

The baseband sub-system 510 is shown to be connected to a user interface 502 to facilitate various input and output of voice and/or data provided to and received from the user. The baseband sub-system 510 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged module comprising:
a packaging substrate having an underside;
an arrangement of conductive features implemented on the underside of the packaging substrate to define an underside area and to allow mounting of the packaged module on a circuit board;
an underside component mounted to the underside of the packaging substrate within the underside area; and
one or more standoff structures implemented on the underside of the packaging substrate and configured to inhibit damage to the underside component when some or all of the arrangement of conductive features collapses during or after mounting of the packaged module on the circuit board.

2. The packaged module of claim 1 wherein the arrangement of conductive features includes an array of conductive pillars.

3. The packaged module of claim 1 wherein the arrangement of conductive features includes a ball grid array.

4. The packaged module of claim 3 wherein the underside component includes a semiconductor die or a surface-mount technology (SMT) device.

5. The packaged module of claim 4 further comprising an upper-side component mounted to an upper side of the packaging substrate, such that the packaged module is a dual-sided module having the ball grid array.

6. The packaged module of claim 5 wherein the underside component and the upper-side component are parts of a radio-frequency circuit.

7. The packaged module of claim 5 further comprising an overmold implemented on the upper side of the packaging substrate.

8. The packaged module of claim 7 further comprising a conformal shield layer implemented to cover an upper surface of the overmold and side walls defined by the overmold and the packaging substrate.

9. The packaged module of claim 1 wherein at least some of the one or more standoff structures is an electrical insulator.

10. The packaged module of claim 1 wherein at least some of the one or more standoff structures is an electrical conductor.

11. The packaged module of claim 10 wherein at least some of the one or more standoff structures is configured to provide an electrical connection between the packaging substrate and the circuit board.

12. The packaged module of claim 10 wherein at least some of the one or more standoff structures is configured to be without an electrical connection with the circuit board.

13. The packaged module of claim 1 wherein at least some of the one or more standoff structures has a melting point that is higher than a melting point of the conductive features.

14. The packaged module of claim 1 wherein at least some of the one or more standoff structures has a ball shape.

15. The packaged module of claim 1 wherein at least some of the one or more standoff structures has a post shape.

16. The packaged module of claim 1 wherein the one or more standoff structures includes a plurality of standoff structures arranged about the underside component.

17. The packaged module of claim 16 wherein the plurality of standoff structures includes a standoff structure positioned near each corner of the underside component.

18. A method for manufacturing a packaged module, the method comprising:
forming or providing a packaging substrate having an underside;
arranging conductive features on the underside of the packaging substrate to allow the packaged module to be capable of being mounted on a circuit board, and to provide an underside area;
mounting an underside component to the underside of the packaging substrate within the underside area; and
implementing one or more standoff structures on the underside of the packaging substrate to inhibit damage to the underside component when some or all of the arrangement of conductive features collapses during or after mounting of the packaged module on the circuit board.

19. A wireless device comprising:
a circuit board configured to receive a plurality of modules;
a transceiver implemented on the circuit board;
an antenna in communication with the transceiver and configured to facilitate either or both of transmission and reception of respective signals; and
a radio-frequency module mounted on the circuit board with an arrangement of conductive features between an underside of the radio-frequency module and the circuit board such that at least a portion of the radio-frequency module is electrically between the transceiver and the antenna, the radio-frequency module further including an underside component mounted to the underside of the radio-frequency module; and
one or more standoff structures implemented between the underside of the radio-frequency module and the circuit board, and configured to inhibit damage to the underside component when some or all of the arrangement of conductive features collapses.

20. (canceled)

21. (canceled)

22. The wireless device of claim 19 wherein at least some of the one or more standoff structures is part of the radio-frequency module.

23. (canceled)
